(19) United States
(12) Patent Application Publication
(10) Pub. No.: US 2014/0027166 A1
(43) Pub. Date: Jan. 30, 2014

(54) TECHNIQUES FOR EFFICIENT WIRE ROUTING IN ELECTRONIC DEVICES

(71) Applicant: barnesandnoble.com llc, New York, NY (US)

(72) Inventors: Karla Robertson, Woodside, CA (US); Nina Joshi, Saratoga, CA (US)

(73) Assignee: barnesandnoble.com llc, New York, NY (US)

(21) Appl. No.: 13/946,545

(22) Filed: Jul. 19, 2013

Related U.S. Application Data
(63) Continuation-in-part of application No. 13/656,364, filed on Oct. 19, 2012.
Application No. 13/656,364 is a continuation-in-part of application No. 13/656,309, filed on Oct. 19, 2012.
(60) Provisional application No. 61/675,122, filed on Jul. 24, 2012.
(60) Provisional application No. 61/675,131, filed on Jul. 24, 2012.
(60) Provisional application No. 61/675,136, filed on Jul. 24, 2012.
(60) Provisional application No. 61/675,140, filed on Jul. 24, 2012.

(51) Int. Cl. H05K 1/18; H05K 3/10

(52) U.S. Cl. CPC H05K 1/18; H05K 3/10
USPC 174/260; 29/850

(57) ABSTRACT

Techniques for efficient routing of wires and electrical components within a device are disclosed. The electrical tape surrounding a device may be folded, cut, or otherwise altered in order to create a trough between distinct device elements. A wire or other component may then be routed within the trough. A wire can be routed, for example, in the space between two device elements (e.g., two battery cells) with the use of a bracket inserted between the cells to provide structural support. The brackets may be placed within the cavity between device elements after cutting a section of the electrical tape. In some embodiments, multiple brackets may be inserted between the device elements, creating a structurally stable trough through which a wire or other component may be routed. After routing a wire through the trough, another electrical part or housing may be fixed above the device elements.

### RELATED APPLICATIONS

This application claims the benefit of U.S. Provisional Application Nos. 61/675,122, 61/675,131, 61/675,136, and 61/675,140 all filed on Jul. 24, 2012. In addition, this application is a continuation-in-part of U.S. patent application Ser. Nos. 13/656,364 and 13/656,309 each filed on Oct. 19, 2012. Each of these applications is herein incorporated by reference in its entirety.

### FIELD OF THE DISCLOSURE

The present disclosure relates to electrical wire routing, and more specifically to routing wires within compact electrical devices.

### BACKGROUND

Typical electronic devices include a number of components populated on a printed circuit board (PCB) that has conductive runs electrically coupling various point of the circuitry. In some cases, additional wires are routed above the PCB to couple other points of the circuitry, such as those points that are not in direct contact with a contact pad of the PCB. Efficiently routing wires and other electrical elements within compact devices involves a number of non-trivial challenges.

### BRIEF DESCRIPTION OF THE DRAWINGS

FIG. 1 shows a cross-sectional view of a circuit having two battery cells enclosed in an electrical tape.

FIG. 2a shows a cross-sectional view of a circuit with the insulating tape folded to form a trough, in accordance with one embodiment of the present invention.

FIG. 2b shows a cross-sectional view of a wire routed through a trough created by folding an insulating tape, in accordance with one embodiment of the present invention.

FIG. 3a shows a cross-sectional view of a circuit with a bracket inserted between battery cells, in accordance with one embodiment of the present invention.

FIG. 3b shows a cross-sectional view of a circuit with a bracket inserted between battery cells, in accordance with another embodiment of the present invention.

FIG. 4 shows a cross sectional view of a wire routed through a trough created by a bracket, in accordance with one embodiment of the present invention.

FIG. 5a shows an overhead view of a bracket inserted between two electrical parts, in accordance with one embodiment of the present invention.

FIG. 5b shows an alternative overhead view of a bracket inserted between two electrical parts, in accordance with one embodiment of the present invention.

FIG. 5c shows an overhead view of two brackets inserted between two electrical parts, in accordance with one embodiment of the present invention.

FIG. 5d shows an overhead view of a bracket inserted between two electrical parts where the bracket overhangs past the edge of the parts, in accordance with one embodiment of the present invention.

FIG. 5e shows an overhead view of two brackets inserted between two electrical parts where the brackets overhang past the edge of the parts, in accordance with one embodiment of the present invention.

FIG. 6 shows a cross-sectional view of a bracket inserted between an electrical part and another structure, in accordance with one embodiment of the present invention.

FIG. 7a shows an overhead, offset view of a bracket, in accordance with one embodiment of the present invention.

FIG. 7b shows a cross-sectional view of a bracket having one lip, in accordance with one embodiment of the present invention.

FIG. 7c shows a cross-sectional view of a bracket having no lip, in accordance with one embodiment of the present invention.

FIG. 7d shows a cross-sectional view of a bracket with a curved trough, in accordance with one embodiment of the present invention.

FIG. 7e shows a cross-sectional view of a bracket with a curved trough and two lips, in accordance with one embodiment of the present invention.

FIG. 7f shows a cross-sectional view of a bracket with a tube-like trough and optional lips, in accordance with one embodiment of the present invention.

FIG. 8 shows a flow diagram of a method for routing a wire in an electrical device, in accordance with one embodiment of the present invention

### DETAILED DESCRIPTION

Techniques for efficient routing of wires and electrical components within a device are disclosed. Electrical devices may have an insulating tape or coating surrounding all or a portion of the device. This tape may isolate cavities within the device that may be underutilized. For example, a Mylar® tape may cover two or more battery cells where there is an unused cavity between each of the cells. A wire can be routed, for example, within a trough formed between the two battery cells by folding or altering the tape at different locations. In other cases, the wire could be routed with the use of a bracket inserted between the cells to provide structural support and electrical reliability, in accordance with an embodiment. The electrical tape surrounding the battery (or other component) may be cut, in some embodiments, in order to expose the cavity between distinct battery cells (or other components). In some specific embodiments, multiple brackets may be inserted between the battery cells at different locations along the cavity, creating a trough through which a wire or other component may be routed. After routing a wire through the trough, another electrical part or housing may be fixed to cover the battery cells, and the routed wire/component. If a bracket is used to provide structural support, the other electrical part may also cover the bracket through which the wire is routed.

General Overview

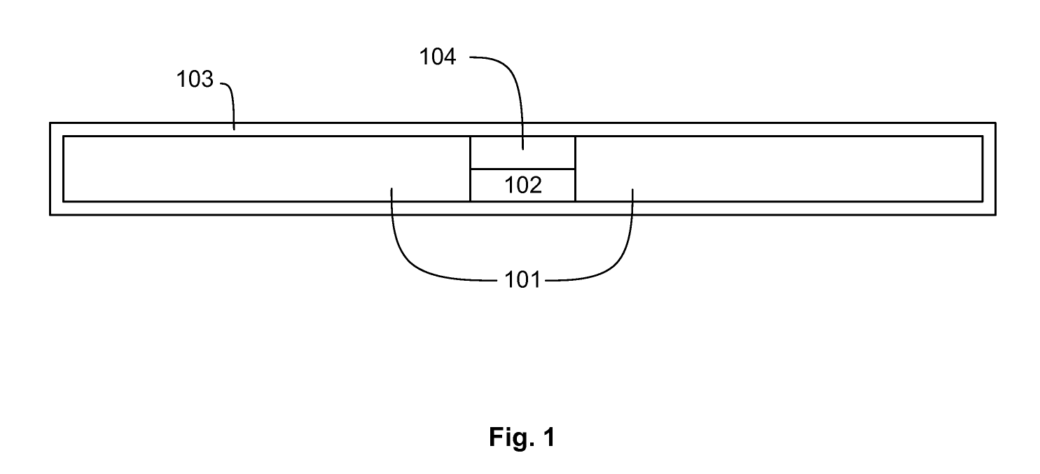

As previously explained, efficiently routing wires and other electrical elements within compact devices involves a number of non-trivial challenges. For instance, electronic devices are present in various form factors, such as, tablets, cell phones, laptops, e-book readers, etc. One solution for routing wires or electrical components within an electrical device is to increase the gap between two electrical parts within the device so as to route the wire between the two parts. Unfortunately, this results in an increase in at least one dimension of the device footprint. FIG. 1 shows a cross-sectional view of two battery cells 101 with a printed circuit board (PCB) 102 between the battery cells, all surrounded by a Mylar® or other electrically insulating tape 103. The electrical tape 103 coating battery cells 101 and PCB 102 may leave an unused cavity 104 between the battery cells.

Thus, and in accordance with an embodiment of the present invention, techniques are disclosed for more effectively routing wires and other electrical components through electronic devices by exploiting underutilized space. According to one embodiment, the Mylar® tape surrounding battery cells may be folded at different locations in order to create a trough through which a wire or other component may be routed. In some cases, the tape may be stretched slightly while it is pushed or folded into the cavity between two battery cells, or otherwise conformally applied so as to follow the contour between the two cells. In another embodiment, the Mylar® tape surrounding battery cells may be removed, cut away at different locations, or otherwise temporarily opened so as to expose the unused cavity between distinct battery cells. One or more molded plastic parts or brackets may then be inserted into the cavity to create structural stability within the cavity so that a wire may be routed through the cavity. The deformed/conformal tape or brackets effectively provide a trough, thereby allowing a wire to be routed through the trough within the bracket. Note that the deformed/conformal tape or bracket also effectively contains the wire, which if placed directly in the cavity might, for instance, move under the battery cell and eventually cause a short-circuit or otherwise create a reliability problem. Further note that embodiments other than wire routing between cells of a battery can also benefit from the techniques provided herein, as will be appreciated in light of this disclosure.

Device Design

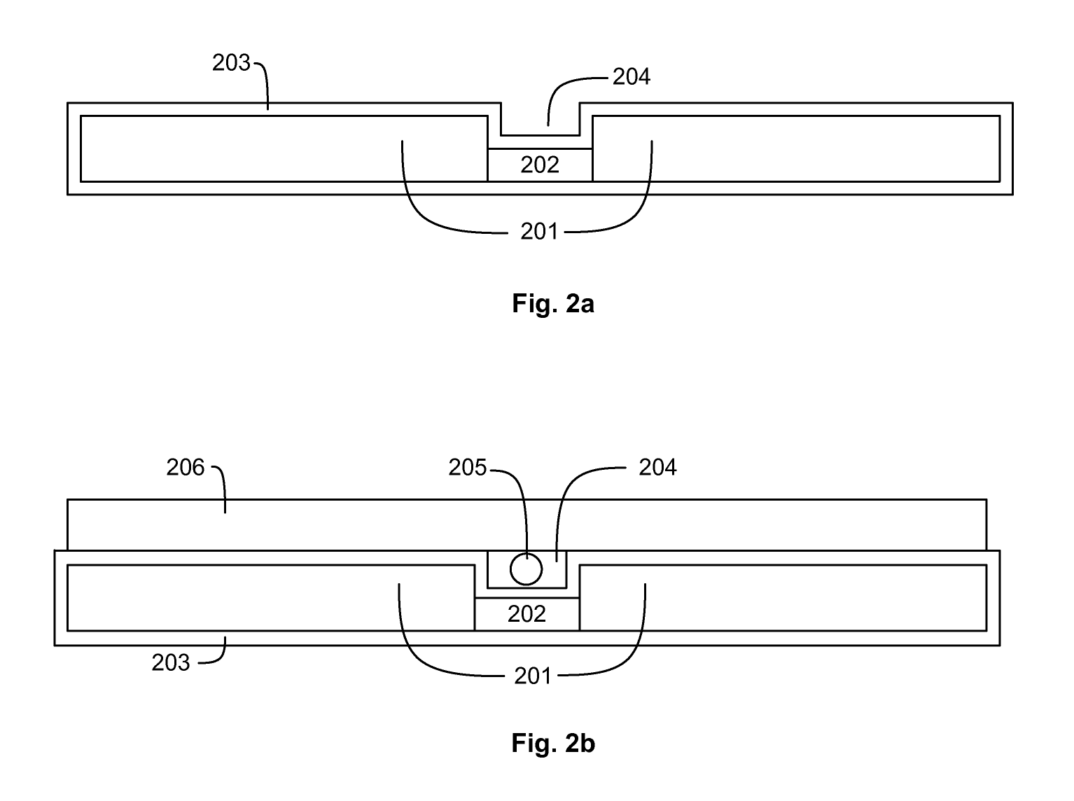

FIG. 2a shows a cross-sectional view of a circuit with the insulating tape folded to form a trough, in accordance with one embodiment of the present invention. As can be seen, this particular example embodiment includes a PCB 202 located between the battery cells 201, and an electrical tape 203 covering a substantial portion of the device. The electrical tape may be made of Mylar®, for example, or some other suitable insulating material. The tape may be folded at different locations, either by hand or using a fixture, to form a cavity or trough, 204. The fixture may be, for example, an implement used to help define the geometry of the trough. In some cases, the electrical tape 203 may initially coat all of, or a substantial portion of the electrical device and the tape may be stretched and pushed between the battery cells 201 to form the trough 204. In some embodiments, each battery cell or electrical part may include its own insulating layer to protect the device from undesired electrical contacts.

FIG. 2b shows a cross-sectional view of a wire routed through a trough created by folding an insulating tape, in accordance with one embodiment of the present invention. This particular example embodiment includes a wire 205 routed within the trough 204 that is created by folding the electrical tape into the cavity between battery cells 201. After forming the trough 204, a wire 205 may be placed within the trough 204, and depending on the size of the trough multiple wires or other components may be routed using these techniques. In this example implementation, the tape 203 may be folded above PCB 202 between the battery cells, and after routing of the wire 205 along a portion of the trough 204, another electrical part or housing 206 may be placed on top of the routed wire and bracket. The electrical part 206 may be, for example, a PCB, another battery cell, or any other electrical device. If desired, an electrical part 206 may include an electrical contact with a wire routed through the trough 204.

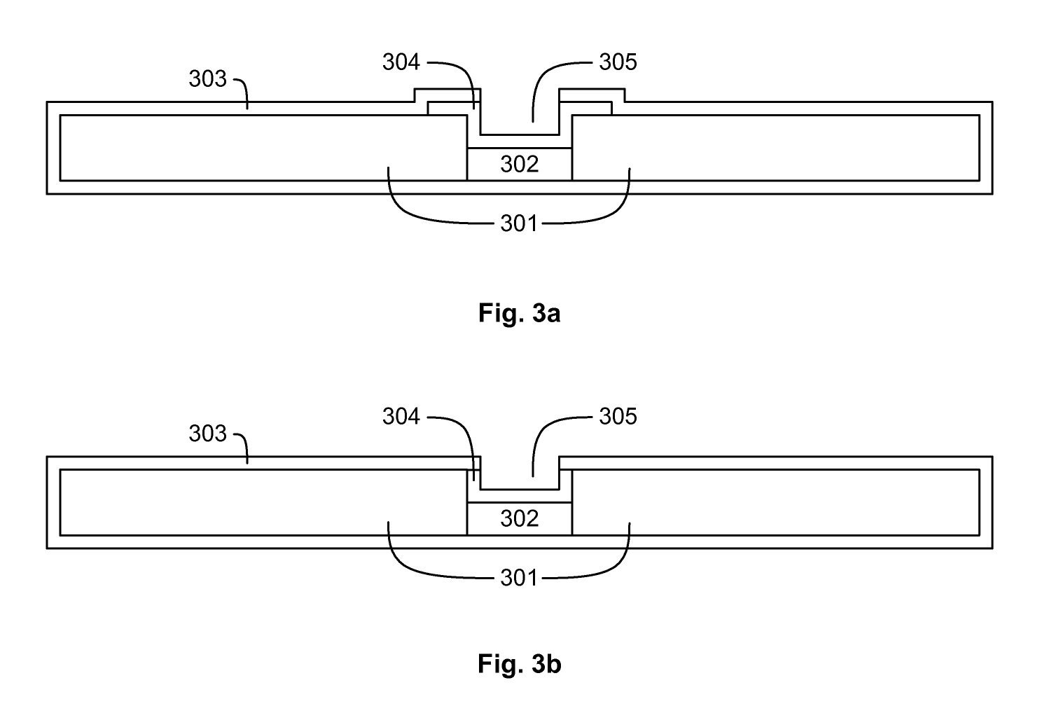

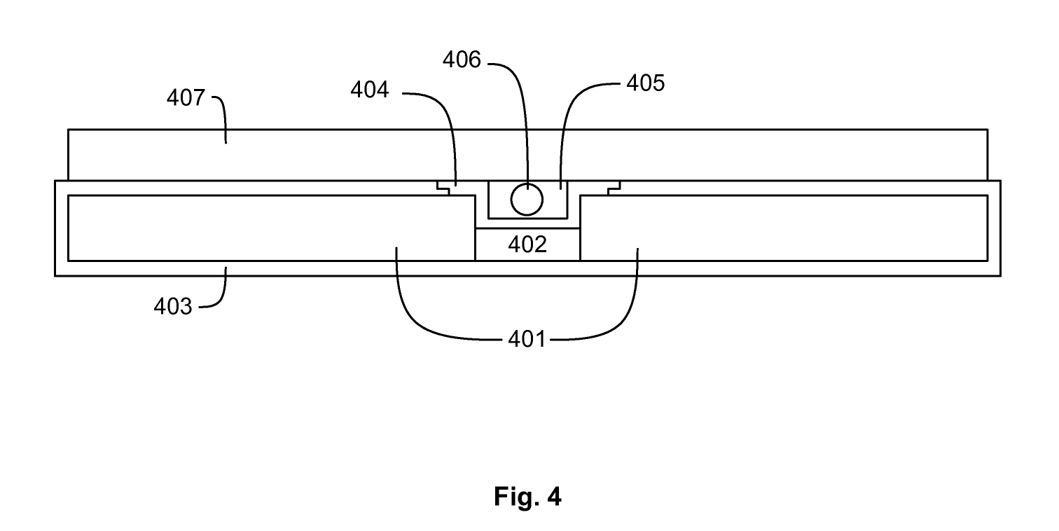

FIG. 3a illustrates a cross-sectional view of an electrical device with a bracket 304 inserted between two cells 301 of a battery, according to one embodiment of the present invention. As can be seen, this particular example embodiment includes a PCB 302 located between the battery cells 301, and an electrical tape 303 covering a substantial portion of the device. The electrical tape may be made of Mylar®, for example, or some other suitable insulating material. The bracket 304 inserted between the battery cells creates a trough 306 that is structurally supported. The electrical tape 303 may initially coat all of, or a substantial portion of the electrical device, in which case the tape may be removed from the area where the bracket is to be placed, allowing the bracket to be inserted between the battery cells. In this particular example embodiment, the ends of electrical tape 303, once cut, may be repositioned above the bracket 304. Alternatively, the ends of tape 303 may be positioned below the lips of bracket 304, as discussed in further detail in reference to FIG. 4.

FIG. 3b illustrates a cross-sectional view of an electrical device with a bracket 304 inserted between two cells 301 of a battery, according to another embodiment of the present invention. As can be seen, this particular example embodiment includes a PCB 302 located between the battery cells 301, and an electrical tape 303 covering a substantial portion of the device. The electrical tape may be made of Mylar®, for example, or some other suitable insulating material. The bracket 304 inserted between the battery cells creates a trough 306 that is structurally supported. The electrical tape 303 may initially coat all of, or a substantial portion of the electrical device, in which case the tape may be removed from the area where the bracket is to be placed, allowing the bracket to be inserted between the battery cells. In this particular example embodiment, the bracket has a low profile and does not include overhanging lips, such that the ends of electrical tape 303, once cut, may be repositioned above the bracket 304 and lie flush with the original surface of the tape. The sides of the bracket may exert pressure against the battery cells, creating a tight fit between the cells. This tight fit may help keep the brackets firmly in place between the electrical parts, as well as help hold the electrical parts firmly in place so they do not compress against or otherwise contact the wire routed through the trough.

The bracket 304 shown may be made, for example, of plastic and may provide structural support for the cavity 104 shown in FIG. 1. As will be further appreciated in light of this disclosure, bracket 304 helps maintain circuit reliability by containing the wire (or other component) routed therein. Multiple brackets of various sizes and dimensions may also be inserted into portions of the cavity between the battery cells. In other embodiments, one or more brackets may be inserted between other parts of an electrical device (other than battery cells) where such a bracket may be desirable for providing structural support for inserting a wire or other component in unused cavities within a device. Each battery cell or electrical part may include its own insulating layer to protect the device from undesired electrical contacts.

FIG. 4 illustrates a cross-sectional view of an electrical device with a wire routed between two cells of a battery, according to one embodiment of the present invention. This particular example embodiment includes a wire 406 routed within the trough 405 that is created by bracket 404 inserted in the cavity between battery cells 401. One or more brackets 404 may be inserted in the opening of electrical tape 403 and the brackets may be placed at different locations within the cavity between battery cells 401. In this particular example, the ends of electrical tap 403 are held in place against the battery cells 401 by the lips of bracket 404. After insertion of the brackets, a wire 406 may be placed within one or more brackets within the trough 405. Depending on the size of the trough created by the brackets, multiple wires or other components may be routed using these techniques. In this example implementation, the bracket 404 is inserted above PCB 402 between the battery cells, and after routing of the wire 406 along a portion of the trough 405, another electrical part or housing 407 may be placed on top of the routed wire and bracket. The electrical part 407 may be, for example, a PCB, another battery cell, or any other electrical device. If desired, an electrical part 407 may include an electrical contact with a wire routed through the trough 405.

Multiple brackets of various sizes and dimensions may be inserted into portions of the cavity between the battery cells regardless of the dimensions of the cavity. The brackets inserted between the battery cells may have a degree of elasticity, such that they can fit tightly or snap into place between the cells. Such a tight fit may provide increased support for the trough as well as help hold the battery cells firmly in place so they do not compress against or otherwise contact the wire routed through the trough. This tight fit may also help keep the brackets themselves firmly in place between the battery cells. In other embodiments, one or more brackets may be inserted between other parts of an electrical device (other than battery cells) where such a bracket may be desirable for providing structural support for inserting a wire or other component in unused cavities within a device. The brackets may be shaped and configured as needed to utilize the available underutilized space regardless of the shape of the space or cavity.

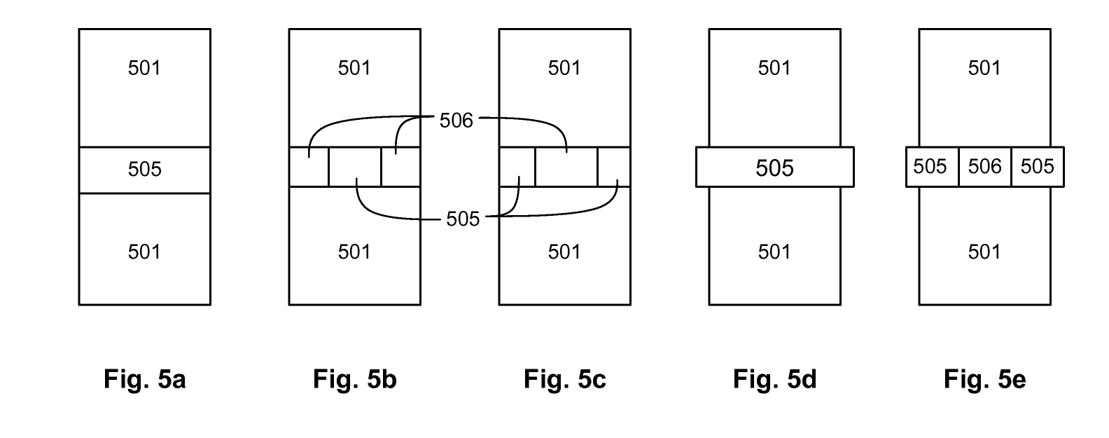

FIG. 5a-5e show overhead views of various placements of one or more brackets between parts of an electrical device, in accordance with various embodiments of the present invention. In the particular embodiment shown in FIG. 5a, a single bracket 505 is inserted along the entire length of the cavity between the electrical parts 501. In one embodiment, the electrical parts 501 are two cells of a battery with the bracket located between them. A wire or other component may then be routed through the trough created by bracket 505. In the particular embodiment shown in FIG. 5b, one bracket 505 is inserted between the battery cells 501 to provide structural support and the bracket does not extend the entire length of the electrical device. This implementation leaves unbracketed cavities 506 between the battery cells, which may be acceptable in some applications. In the particular embodiment shown in FIG. 5c, two brackets 505 are inserted on the edges of the electrical device between battery cells 501 leaving a structurally stable cavity 506 between the brackets. A wire may be routed through the cavities 506 and through the trough of one or more brackets 505. The positioning of brackets 505 between the battery cells 501 may be determined, among other factors, based on the sizes of the cells. As mentioned above, each battery cell or electrical part may include its own electrically insulating layer, such that electrical insulation is not a problem in the cavities 506 where a bracket is not present.

FIGS. 5d and 5e show overhead views of various bracket placements where the brackets overhang beyond the edge of the electrical device. In FIG. 5d, a single bracket is inserted between battery cells 501 and extends the entire length of the electrical device and overhangs beyond the edges. In FIG. 5e, two brackets 505 are inserted on the edges of the electrical device between battery cells 501, and the brackets overhang beyond the edges of the device leaving an unbracketed cavity 506 between the two brackets. The overhang of the brackets may allow a wire that is routed within the trough created by the brackets to be easily connected to additional electrical devices that may be connected to the device shown in FIGS. 5a-5e, and without requiring an increase in the device footprint or existing layout. The various embodiments discussed are for illustration purposes only, and they are not intended to be an exhaustive list of bracket configurations. For instance, although the cavities illustrated in FIGS. 4a-4e are shown as single, continuous lines without junctions or bends, the cavities located between battery cells or other electrical parts may include curves, bends, multiple junctions, intersections of cavities, etc. The techniques disclosed herein are equally applicable to those implementations, and many alternative configurations will be apparent to those skilled in the art in light of this disclosure.

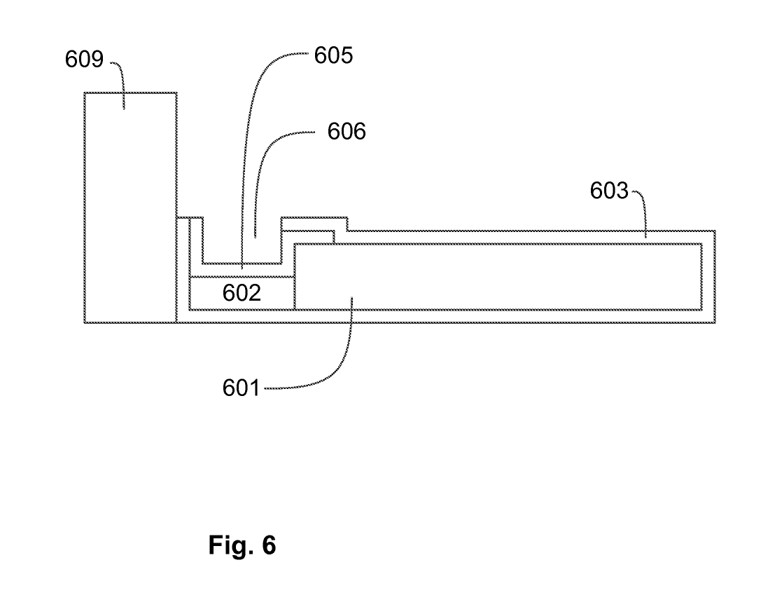

FIG. 6 shows a cross-sectional view of an electrical device with a bracket inserted between a battery cell and a housing wall, according to one embodiment of the present invention. In this particular embodiment, the bracket 605 may be inserted between a battery cell 601 and housing or other structure 609 and above a PCB or substrate 602 to utilize space between the battery cell and the housing wall. In this example, the tape 603 around the electrical device may be altered or cut in order to expose the cavity above the PCB 602 and beside battery cell 601. The bracket may then be inserted within the cavity, forming a trough 606 that can be utilized for routing a wire or other component between the battery cell and housing wall. As illustrated in FIG. 6, the bracket in this implementation does not include an overlapping lip on both sides of the trough of the bracket. The brackets used for routing a wire in underutilized cavities within an electrical device may be of different shapes and configurations and may conform to whatever underutilized cavity space is available.

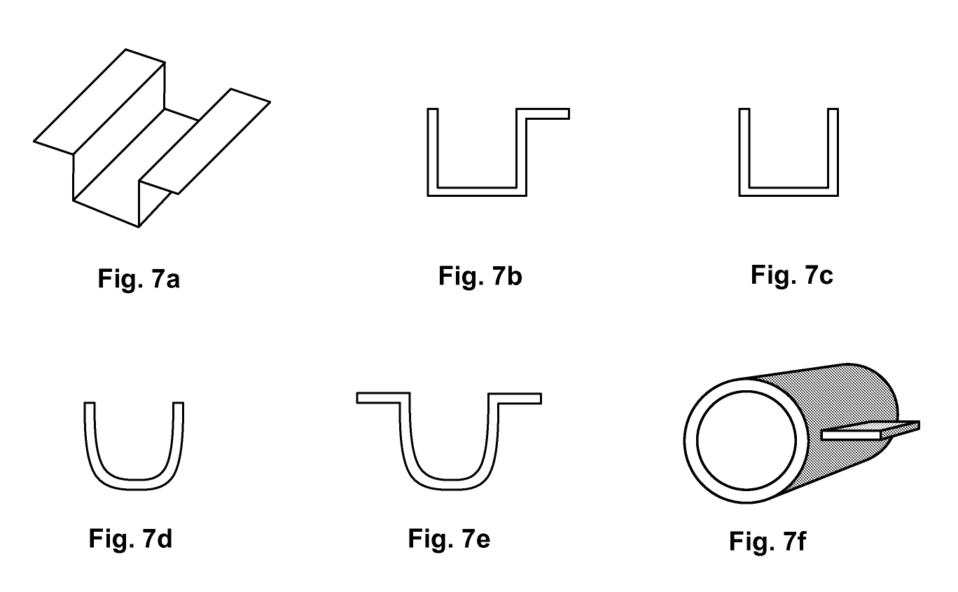

FIGS. 7a-7e illustrate different bracket configurations, according to multiple embodiments of the present invention. FIG. 7a illustrates one embodiment of a bracket that may be inserted in the cavity between two electrical parts. The bracket includes a trough running along the length of the bracket and has two lips that may overhang over the neighboring electrical parts. FIG. 7b is a cross-sectional view of another bracket configuration having only one lip, as previously disclosed in reference to FIG. 6. FIG. 7c is a cross-sectional view of an alternative bracket configuration without any lips that may be inserted between two electrical parts in order to provide structural strength for wire routing. FIG. 7d is a cross-sectional view of another bracket configuration with a concave trough without lips that might overhang an electrical part. FIG. 7e is a cross-sectional view of yet another bracket configuration with a concave trough, having two lips that may be inserted between two electrical parts such that the lips cover a portion of the electrical parts. FIG. 7f is a cross-sectional view of yet another bracket configuration with a tube-like trough, which may also be configured with one or two lips if so desired. In some such cases, the tube may be a mesh like material, so as to allow visibility into the tube. The upper portions of the brackets shown in FIGS. 7d and 7e may be compressed together for easier insertion within the underutilized cavity space, and once inserted the bracket may expand creating a tight fit within the cavity space. Such a tight fit may provide increased support for the trough as well as help hold the electrical parts firmly in place so they do not compress against or otherwise contact the wire routed through the trough. This tight fit may also help keep the brackets themselves firmly in place between the electrical parts. The brackets shown in FIGS. 7a, 7b, 7e, and 7f may be inserted such that the lips may cover the ends of the electrical tape surrounding the electrical device, or the ends of the tape may lie over top of them. In other embodiments, the tape may lie over top of the bracket and substantially cover the bracket and trough. In a single wire routing technique, multiple sizes and configurations of brackets may be used depending on the desired wire route. The brackets shown in the foregoing figures are not drawn to scale and many sizes and configurations will be apparent in light of this disclosure.

Methodology

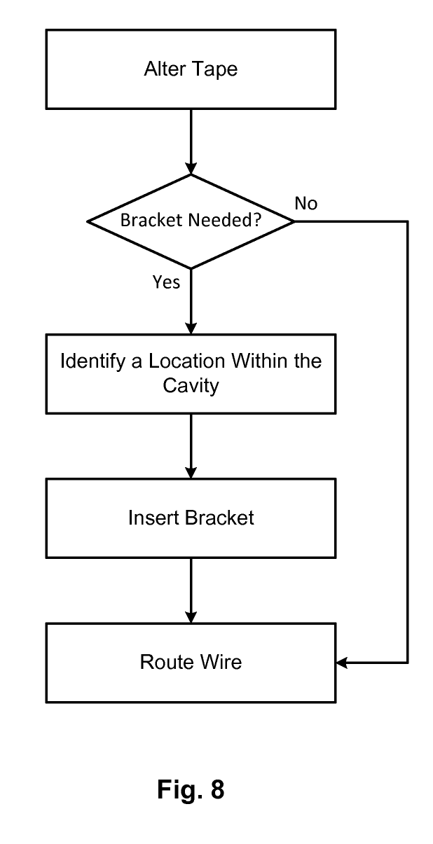

FIG. 8 is a flow diagram illustrating a method for routing a wire within a cavity in an electrical device, according to one embodiment of the present invention. Initially, the electrical device may be entirely or substantially covered in an electrical tape. In some embodiments this tape is made of Mylar®, or some other suitable insulating material. In order to access the underutilized cavities between elements of an electrical device, the tape layer can be altered or cut. The elements of the electrical device could be, for example, battery cells. In one example embodiment, altering the tape may include folding the tape at different locations, either by hand or using an implement, to form a trough within the cavity of the electrical device. The implement may be used, for example, to help define the geometry of the trough. In one such embodiment, the tape may be stretched and pushed into the cavity in order to form the trough. In another example embodiment, the tape is cut above the unused cavity between two battery cells in order to access the cavity. Once the tape has been altered, the method may continue with determining whether a bracket is needed. In some cases, a bracket may be needed to provide added structural support and/or electrical reliability to the trough. If no bracket is needed, one or more wires or other components may be routed within the trough. If a bracket is needed, one or more locations within the cavity can be identified for placement of one or more brackets. The location of the bracket placement may be determined, among other factors, based on the size of the cavity, or the size of the electrical parts or battery cells around which a wire will be routed. In one example embodiment, the placement of the brackets may be determined before altering the electrical tape layer. The brackets may then be inserted into the desired locations within the cavity providing a structurally stable and/or electrically reliable path for wire routing. The brackets may also guide the wire or wires and prevent them from straying from their intended path. The brackets may be inserted such that, if they include a lip (as shown in FIGS. 7a, 7b, 7e, and 7f), the lip may overlap the ends of the electrical tape. Alternatively, the tape may be applied over the bracket after insertion, and in some cases the tape falls flush with the original surface of the tape-coated device. If desired, and adhesive material may be used to reapply the electrical tape around the electrical device, either above or underneath the brackets (or new tape may be provisioned). After bracket insertion, one or more wires or other components may be routed within the trough of the brackets. If the brackets do not extend the entire length of the cavity, the wire may pass through the troughs of one or more brackets and through the structurally stable cavities surrounding the brackets.

Numerous variations and embodiments will be apparent in light of this disclosure. One example embodiment of the present invention provides a device including a substrate, at least one electrical part in contact with the substrate, a cavity neighboring the electrical part and above the substrate, an electrical tape covering a substantial portion of the outside of the at least one electrical part and deformed into the cavity thereby providing a trough, and an electrical component routed through the trough. In some cases, the substrate is a printed circuit board (PCB). In some cases, the at least one electrical part includes two components separated by the cavity. In some such cases, the two components are each battery cells. In other such cases, the two battery cells and the substrate are packaged in the electrical tape. In some cases, the tape is deformed into the cavity by pressing the tape into the cavity by hand or using an implement. In some such cases, the implement is used to define the geometry of the trough. In some cases, the tape substantially conforms to the substrate and the at least one electrical part. In some cases, the device includes at least one of a housing and/or an electrical part covering a substantial portion of the electrical component. In some cases, the electrical component includes a wire.

Another example embodiment of the present invention provides an electrical device including a printed circuit board (PCB), at least two battery cells in contact with the PCB, a cavity with three or more boundaries comprising at least the PCB and one edge of each of the two battery cells, electrical tape surrounding a substantial portion of the outside of the at least two battery cells and folded to form a trough within the cavity, and at least one wire routed within the trough. In some cases, the electrical tape folded within the cavity is stretched. In some such cases, the trough within the cavity has a shape defined by an implement used to stretch the tape into the cavity. In some cases, the electrical tape is folded to substantially conform to the PCB and one edge of each of the two battery cells. In some cases, the electrical device includes at least one of a housing and/or an electrical part covering a substantial portion of the electrical component.

Another example embodiment of the present invention provides a method for routing an electrical component including folding a portion of an electrical tape within a cavity next to at least one electrical part and above a substrate, and depositing the electrical component above the electrical tape within the cavity. In some cases, the at least one electrical part includes two components held together by the electrical tape and separated by the cavity. In some cases, folding a portion of the electrical tape within the cavity includes pressing the tape into the cavity. In some such cases, an implement is used to define the geometry of the trough. In some cases, folding a portion of the electrical tape within the cavity includes stretching the tape into the cavity

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto

What is claimed is:

1. A device, comprising:
a substrate;
at least one electrical part in contact with the substrate;
a cavity neighboring the electrical part and above the substrate;
an electrical tape covering a substantial portion of the outside of the at least one electrical part and deformed into the cavity thereby providing a trough; and
an electrical component routed through the trough.

2. The device of claim 1 wherein the substrate is a printed circuit board (PCB).

3. The device of claim 1 wherein the at least one electrical part comprises two components separated by the cavity.

4. The device of claim 3 wherein the two components are each battery cells.

5. The device of claim 3 wherein the two battery cells and the substrate are packaged in the electrical tape.

6. The device of claim 1 wherein the tape is deformed into the cavity by pressing the tape into the cavity by hand or using an implement.

7. The device of claim 6 wherein the implement is used to define the geometry of the trough.

8. The device of claim 1 wherein the tape substantially conforms to the substrate and the at least one electrical part.

9. The device of claim 1 further comprising at least one of a housing and/or an electrical part covering a substantial portion of the electrical component.

10. The device of claim 1 wherein the electrical component comprises a wire.

11. An electrical device comprising:
a printed circuit board (PCB);
at least two battery cells in contact with the PCB;
a cavity with three or more boundaries comprising at least the PCB and one edge of each of the two battery cells;
electrical tape surrounding a substantial portion of the outside of the at least two battery cells and folded to form a trough within the cavity; and
at least one wire routed within the trough.

12. The electrical device of claim 11 wherein the electrical tape folded within the cavity is stretched.

13. The electrical device of claim 12 wherein the trough within the cavity has a shape defined by an implement used to stretch the tape into the cavity.

14. The electrical device of claim 11 wherein the electrical tape is folded to substantially conform to the PCB and one edge of each of the two battery cells.

15. The electrical device of claim 11 further comprising at least one of a housing and/or an electrical part covering a substantial portion of the electrical component.

16. A method for routing an electrical component, comprising:
folding a portion of an electrical tape within a cavity next to at least one electrical part and above a substrate; and
depositing the electrical component above the electrical tape within the cavity.

17. The method of claim 16 wherein the at least one electrical part comprises two components held together by the electrical tape and separated by the cavity.

18. The method of claim 16 wherein folding a portion of the electrical tape within the cavity includes pressing the tape into the cavity.

19. The method of claim 18 wherein an implement is used to define the geometry of the trough.

20. The method of claim 16 wherein folding a portion of the electrical tape within the cavity includes stretching the tape into the cavity.
